(19) United States
(12) Patent Application Publication
(10) Pub. No.: US 2011/0163430 A1
(43) Pub. Date: Jul. 7, 2011

(54) Leadframe Structure, Advanced Quad Flat No Lead Package Structure Using the Same, and Manufacturing Methods Thereof

(75) Inventors: Yuyong Lee, Paju-Si (KR); Seokbong Kim, Paju-Si (KR)

(73) Assignee: Advanced Semiconductor Engineering, Inc.

(21) Appl. No.: 12/683,426

(22) Filed: Jan. 6, 2010

(51) Int. Cl. H01L 23/495; H05K 3/02; H01L 21/60

(52) U.S. Cl. 257/676; 29/846; 438/123; 257/E23.031; 257/E21.506

(57) ABSTRACT

A package structure and related methods are described. In one embodiment, the package structure includes a chip, a plurality of leads disposed around and electrically coupled to the chip, and a package body formed over the chip and the plurality of leads. At least one lead includes a central metal layer having an upper surface and a lower surface, a first protruding metal block having an upper surface and extending upwardly from the upper surface of the central metal layer, a second protruding metal block having a lower surface and extending downwardly from the lower surface of the central metal layer, a first finish layer on the upper surface of the first protruding metal block, and a second finish layer on the lower surface of the second protruding metal block. The package body substantially covers the first protruding metal block and the first finish layer of each of the leads.

### FIELD OF THE INVENTION

The present invention generally relates to electronic device packaging. More particularly, the present invention relates to a leadframe structure and an advanced quad flat no lead (aQFN) package structure using the same, and manufacturing methods thereof.

### BACKGROUND

Higher performance and increased I/O counts in a smaller package are in great demand, especially in the RE/wireless, portable application, and PC peripheral markets. Advanced lead frame packaging, including quad flat no lead (QFN) packages and enhanced leadless leadframe-based packages, has become widely accepted and is typically suitable for chip packages including high-frequency transmission, such as over RF bandwidths.

For the QFN package structure, the die pad and surrounding contact terminals (lead pads) are typically fabricated from a planar leadframe substrate. The QFN package structure generally is soldered to the printed circuit board (PCB) using surface mounting technology (SMT). Accordingly, the die pad and/or contact terminals/pads of the QFN package structure should be designed to fit well within the packaging process capabilities, such as by facilitating surface mounting, as well as to promote good long term solder joint reliability.

It is against this background that a need arose to develop the leadframe structure, package structure, and related methods described herein.

### SUMMARY

Accordingly, one aspect of the present invention is directed to a leadframe structure, an advanced quad flat no lead (aQFN) package structure using the same, and a manufacturing method thereof.

In one innovative aspect, the invention relates to a package structure. In one embodiment, the package structure includes a chip, a plurality of leads disposed around the chip and electrically coupled to the chip, and a package body formed over the chip and the plurality of leads. At least one of the plurality of leads includes: (a) a central metal layer having an upper surface and a lower surface; (b) a first protruding metal block extending upwardly from the upper surface of the central metal layer, and having an upper surface; (c) a second protruding metal block extending downwardly from the lower surface of the central metal layer, and having a lower surface; (d) a first finish layer on the upper surface of the first protruding metal block; and (e) a second finish layer on the lower surface of the second protruding metal block. The package body substantially covers the first protruding metal block and the first finish layer of each of the plurality of leads.

In addition, the first protruding metal block may extend upwardly from the upper surface of the central metal layer by between thirty-five percent and one hundred percent of a thickness of the central metal layer, and the second protruding metal block may extend downwardly from the lower surface of the central metal layer by between thirty-five percent and one hundred percent of the thickness of the central metal layer.

In addition, the first protruding metal block may have a side surface that is substantially perpendicular to the upper surface of the first protruding metal block.

In addition, the package may include a die pad having an upper surface and a lower surface, the chip being disposed on the upper surface of the die pad. The package may also include a first metal layer having an upper surface and a lower surface, the die pad being disposed on the upper surface of the first metal layer, where the first metal layer is of substantially the same thickness as the central metal layer. The package may also include a second metal layer having an upper surface and a lower surface, the first metal layer being disposed on the upper surface of the second metal layer, where the second metal layer is of substantially the same thickness as the second protruding metal block. The package may also include a metal finish layer disposed on the lower surface of the second metal layer.

In addition, the upper surface of the die pad may be in substantially the same plane as the upper surface of the central metal layer.

In addition, the die pad may extend upwardly from the upper surface of the first metal layer by between thirty-five percent and one hundred percent of a thickness of the first metal layer.

In another innovative aspect, the invention relates to a method of forming a leadframe structure. In one embodiment, the method includes providing a metal sheet, a first patterned photoresist layer formed on an upper surface of the metal sheet, and a second patterned photoresist layer formed on a lower surface of the metal sheet, where a distance between the upper surface and the lower surface corresponds to a thickness of the metal sheet. The method further includes forming a first metal layer on areas of the upper surface of the metal sheet not covered by the first patterned photoresist layer and forming a second metal layer on areas of the lower surface of the metal sheet not covered by the second patterned photoresist layer, where the first metal layer extends upwardly from the upper surface of the metal sheet by between thirty-five percent and one hundred percent of the thickness of the metal sheet, and wherein the second metal layer extends downwardly from the lower surface of the metal sheet by between thirty-five percent and one hundred percent of the thickness of the metal sheet. The method further includes forming a first finish layer on the first metal layer and forming a second finish layer on the second metal layer, and removing the first and second patterned photoresist layers.

In addition, the first metal layer may include a plurality of protruding metal blocks each including an upper surface and a side surface. The side surfaces of each of the plurality of protruding metal blocks may be substantially perpendicular to the upper surface of the metal sheet.

In addition, the first metal layer and the second metal layer may be formed by performing a plating process.

In addition, the first finish layer and the second finish layer may be formed by performing a surface finishing process.

In addition, the surface finishing process may include at least one of an electroplating process, an electroless plating process, and an immersion process.

In another innovative aspect, the invention relates to a method of making a package structure. In one embodiment, the method includes providing a metal sheet having an upper surface and a lower surface, a plurality of first protruding metal blocks formed on the upper surface, a first finish layer formed on the plurality of first protruding metal blocks, a plurality of second protruding metal blocks formed on the lower surface, and a second finish layer formed on the plurality of second protruding metal blocks. The method further includes electrically coupling a chip to at least a first protruding block included in the plurality of first protruding metal blocks, and forming a molding compound over the metal sheet to encapsulate the chip, the plurality of first protruding metal blocks, and the first finish layer formed on the plurality of first protruding metal blocks. The method further includes etching through areas on the lower surface of the metal sheet until the molding compound is exposed, the etching using the second finish layer as an etching mask, so as to define a plurality of leads.

In addition, the plurality of first protruding metal blocks may extend upwardly from the upper surface of the metal sheet by between thirty-five percent and one hundred percent of a thickness of the metal sheet. The plurality of second protruding metal blocks may extend downwardly from the lower surface of the metal sheet by between thirty-five percent and one hundred percent of the thickness of the metal sheet.

In addition, the providing may include forming a first patterned photoresist layer on the upper surface of the metal sheet and a second patterned photoresist layer on the lower surface of the metal sheet. The providing may also include forming the plurality of first protruding metal blocks on areas of the upper surface of the metal sheet that are not covered by the first patterned photoresist layer, and forming the plurality of second protruding metal blocks on areas of the lower surface of the metal sheet that are not covered by the second patterned photoresist layer. The providing may also include forming the first finish layer on the plurality of first protruding metal blocks and forming the second finish layer on the plurality of second protruding metal blocks, and may also include removing the first and second patterned photoresist layers.

In addition, the plurality of first protruding metal blocks each may include a side surface that is substantially perpendicular to the upper surface of the metal sheet.

In addition, the plurality of first protruding metal blocks and the plurality of second protruding metal blocks may be formed by performing a plating process.

In addition, the first finish layer and the second finish layer may be formed by performing a surface finishing process.

In addition, the providing may include forming a first central protruding block on the upper surface of the metal sheet and forming a second central protruding block on the lower surface of the metal sheet, after forming the first and second patterned photoresist layers. The providing may include attaching the chip to an upper surface of the first central protruding block. The molding compound may encapsulate the first central protruding block.

In addition, the first central protruding block may extend upwardly from the upper surface of the metal sheet by between thirty-five percent and one hundred percent of the thickness of the metal sheet. The second central protruding block may extend downwardly from the lower surface of the metal sheet by between thirty-five percent and one hundred percent of the thickness of the metal sheet.

In addition, the upper surface of the first central protruding block may be substantially in the same plane as an upper surface of the first protruding block included in the plurality of first protruding metal blocks.

In another innovative aspect, the invention relates to a leadframe structure. In one embodiment, the leadframe structure includes a metal sheet having an upper surface and a lower surface, and a first central protruding block formed on the upper surface. The leadframe structure further includes a plurality of first protruding metal blocks formed on the upper surface and surrounding the first central protruding block, and a first finish layer formed on the plurality of first protruding metal blocks. The leadframe structure further includes a plurality of second protruding metal blocks formed on the lower surface, and a second finish layer formed on the plurality of second protruding metal blocks.

In addition, the plurality of first protruding metal blocks may extend upwardly from the upper surface of the metal sheet by between thirty-five percent and one hundred percent of a thickness of the metal sheet, and the plurality of second protruding metal blocks may extend downwardly from the lower surface of the metal sheet by between thirty-five percent and one hundred percent of the thickness of the metal sheet.

In addition, the locations of the plurality of first protruding metal blocks may correspond to the locations of the plurality of second protruding metal blocks.

In addition, the plurality of first protruding metal blocks and the plurality of second protruding metal blocks may include at least one of copper and copper alloys.

In addition, the plurality of first protruding metal blocks may have a different material composition than the plurality of second protruding metal blocks.

In addition, the first finish layer and the second finish layer may include at least one of nickel, gold, palladium, tin, and silver.

In addition, the first finish layer may have a different material composition than the second finish layer.

In addition, the leadframe structure may also include a second central protruding block formed on the lower surface of the metal sheet, and a location of the second central protruding block may correspond to a location of the first central protruding block. In addition, an upper surface of each of the plurality of first protruding metal blocks may be substantially coplanar and may define a first plane. A side surface of each of the plurality of first protruding metal blocks may be substantially perpendicular to the first plane.

### BRIEF DESCRIPTION OF THE DRAWINGS

The accompanying drawings are included to provide a further understanding of some embodiments of the invention, and are incorporated in and constitute a part of this specification. The drawings illustrate embodiments of the invention and, together with the description, serve to explain the principles of some embodiments of the invention.

FIGS. 1A through 1H are schematic views showing methods of forming a leadframe structure and making an advanced quad flat no lead (aQFN) package structure according to embodiments of the present invention.

FIG. 2 shows a schematic cross-sectional view of one example of the package structure according to an embodiment of the present invention.

FIG. 3A shows an exemplary cross-sectional view of the leadframe structure according to another embodiment of the present invention.

FIG. 3B is an exemplary top view of the leadframe structure of FIG. 3A.

FIG. 4 shows an exemplary cross-sectional view of the leadframe structure according to another embodiment of the present invention.

### DETAILED DESCRIPTION

Reference will now be made in detail to some embodiments of the invention, examples of which are illustrated in the accompanying drawings. Wherever possible, the same reference numbers are used in the drawings and the descriptions to refer to the same or like parts.

### DEFINITIONS

The following definitions apply to some of the aspects described with respect to some embodiments of the invention. These definitions may likewise be expanded upon herein.

As used herein, the singular terms “a”, “an” and “the” include plural referents unless the context clearly dictates otherwise. Thus, for example, reference to a protruding metal block can include multiple protruding metal blocks unless the context clearly dictates otherwise.

As used herein, the term “set” refers to a collection of one or more components. Thus, for example, a set of layers can include a single layer or multiple layers. Components of a set also can be referred to as members of the set. Components of a set can be the same or different. In some instances, components of a set can share one or more common characteristics.

As used herein, the term “adjacent” refers to being near or adjoining. Adjacent components can be spaced apart from one another or can be in actual or direct contact with one another. In some instances, adjacent components can be connected to one another or can be formed integrally with one another.

As used herein, terms such as “inner,” “top,” “bottom,” “above,” “below,” “upwardly,” “downwardly,” “side,” and “lateral” refer to a relative orientation of a set of components, such as in accordance with the drawings, but do not require a particular orientation of those components during manufacturing or use.

As used herein, the terms “connect”, “connected” and “connection” refer to an operational coupling or linking. Connected components can be directly coupled to one another or can be indirectly coupled to one another, such as via another set of components.

As used herein, the terms “substantially” and “substantial” refer to a considerable degree or extent. When used in conjunction with an event or circumstance, the terms can refer to instances in which the event or circumstance occurs precisely as well as instances in which the event or circumstance occurs to a close approximation, such as accounting for typical tolerance levels of the manufacturing operations described herein.

As used herein, the terms “conductive” refers to an ability to transport an electric current. Electrically conductive materials typically correspond to those materials that exhibit little or no opposition to flow of an electric current. One measure of electrical conductivity is in terms of Siemens per meter (“S·m⁻¹”). Typically, an electrically conductive material is one having a conductivity greater than about 10⁴ S·m⁻¹, such as at least about 10⁵ S·m⁻¹ or at least about 10⁶ S·m⁻¹. Electrical conductivity of a material can sometimes vary with temperature. Unless otherwise specified, electrical conductivity of a material is defined at room temperature.

Aspects of the present invention can be used for fabricating various package structures, such as stacked type packages, multiple-chip packages, or high frequency device packages.

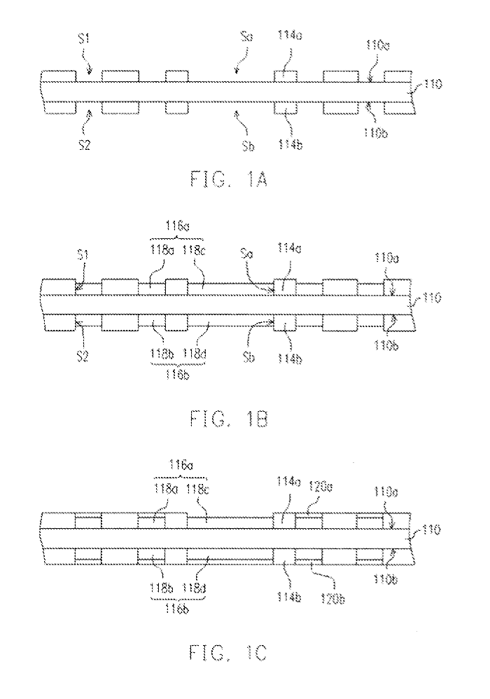

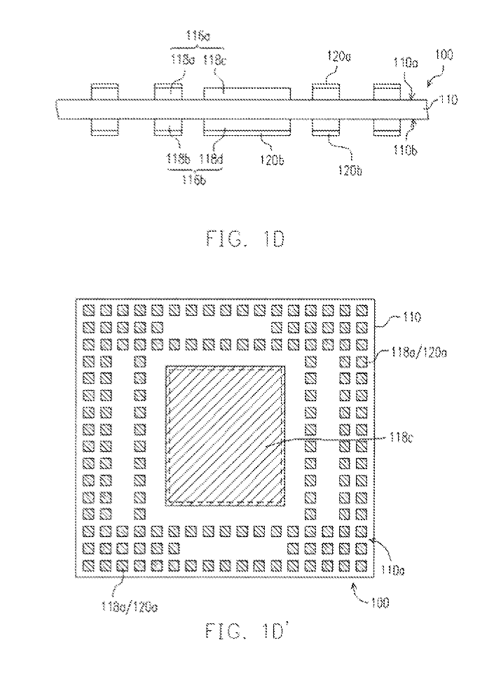

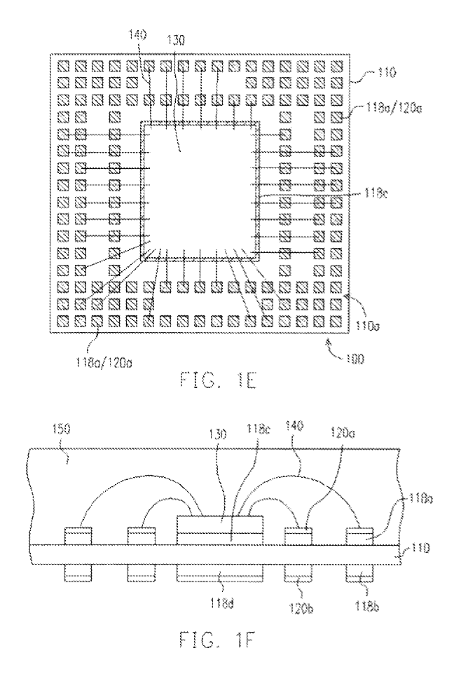

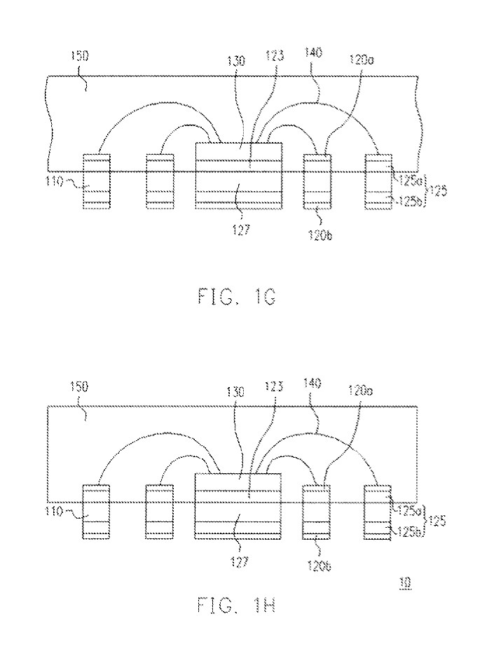

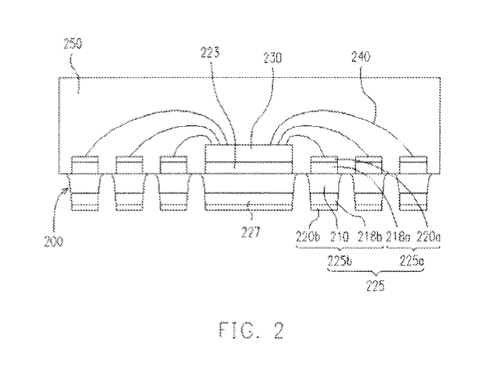

FIGS. 1A through 1H are schematic views showing methods of forming a leadframe structure and making an advanced quad flat no lead (aQFN) package structure according to embodiments of the present invention. FIGS. 1A-1D and 1F-1H are shown in cross-sectional views, while FIGS. 1D′-1E are shown in top views.

As shown in FIG. 1A, a metal sheet 110 having an upper surface 110a and a lower surface 110b is provided. The metal sheet 110 may include, for example, copper, a copper alloy, or other applicable metal materials. A distance between the upper surface 110a and the lower surface 110b corresponds to a thickness of the metal sheet 110. Next, still referring to FIG. 1A, a first patterned photoresist layer 114a is formed on the upper surface 110a of the metal sheet 110, and a second patterned photoresist layer 114b is formed on the lower surface 110b of the metal sheet 110. The first and second photoresist layers 114a/114b can be formed by laminating dry film resist layers on the upper surface 110a and the lower surface 110b of the metal sheet 110, respectively, under exposure and then by developing to form patterns in the dry film resist layers. Although the patterns of the first and second photoresist layers 114a/114b in FIG. 1A are shown as identical, the pattern of the first photoresist layer 114a can be different to that of the second photoresist layer 114b, depending on the product design.

Next, referring to FIG. 1B, using the first patterned photoresist layer 114a and the second patterned photoresist layer 114b as masks, a plating process is performed to respectively form a first metal layer 116a on areas of the upper surface 110a of the metal sheet 110 not covered by the first photoresist layer 114a, and a second metal layer 116b on areas of the lower surface 110b of the metal sheet 110 not covered by the second photoresist layer 114b. The first metal layer 116a extends upwardly from the upper surface 110a, and the second metal layer 116b extends downwardly from the lower surface 110b. The first and second metal layers 116a/116b may include, for example, copper, copper alloys, or other applicable metal materials. The first metal layer 116a can have a material composition that is the same as or different from the material composition of the second metal layer 116b. The thickness of the first and second metal layers 116a/116b can be about 5-25 micrometers, and the ratio of the thickness of the first and second metal layers 116a/116b to the thickness of the metal sheet 110 may range from 0.1-1, 0.25-1, 0.35-1, 0.4-1, 0.5-1, 0.75-1, and 0.9-1, for example. Put another way, the first metal layer 116a may extend upwardly from the upper surface 110a, and the second metal layer may extend downwardly from the lower surface 110b, by, for example, a range of 10-100 percent, 25-100 percent, 35-100 percent, 40-100 percent, 50-100 percent, 75-100 percent, and 90-100 percent of the thickness of the metal sheet 110. The thickness of the first and second metal layers 116a/116b may also be substantially equal to the thickness of the metal sheet 110.

The first metal layer 116a includes a plurality of first protruding metal blocks 118a formed within the openings S1 of the first patterned photoresist layer 114a. The first metal layer 116a further includes a first central protruding block 118c within a central cavity Sa of the first patterned photoresist layer 114a. The second metal layer 116b includes a plurality of second protruding metal blocks 118b formed within the openings S2 of the second patterned photoresist layer 114b. The second metal layer 116b further includes a second central protruding block 118d within a central cavity Sb of the second patterned photoresist layer 114b. The first protruding metal blocks 118a and the first central protruding block 118c may extend upwardly from the upper surface 110a by a range of 10-100 percent, 25-100 percent, 35-100 percent, 40-100 percent, 50-100 percent, 75-100 percent, and 90-100 percent of the thickness of the metal sheet 110. In one embodiment, the first protruding metal blocks 118a and the first central protruding block 118c may extend upwardly from the upper surface 110a by substantially the same amount. The second protruding metal blocks 118b and the second central protruding block 118d may extend downwardly from the lower surface 110b by a range of 10-100 percent, 25-100 percent, 35-100 percent, 40-100 percent, 50-100 percent, 75-100 percent, and 90-100 percent of the thickness of the metal sheet 110. In one embodiment, the second protruding metal blocks 118b and the second central protruding block 118d may extend downwardly from the lower surface 110b by substantially the same amount.

The first/second metal blocks 118a/118b are disposed surrounding the first/second central block 118c/118d. The locations of the first metal blocks 118a correspond to the locations of the second metal blocks 118b, and the first/second metal blocks 118a/118b are to-be-formed inner/outer leads. The first/second metal blocks 118a/118b may be arranged in rows, columns or arrays. From the top view, the shape of the first/second metal blocks 118a/118b may be square (as shown in FIG. 1D′), round, or polygonal, for example. The first central block 118c can function as the die pad, while the second central block 118d may function as the heat sink. The first central block 118c and the second central block 118d may include a metal, a metal alloy, or some other conductive material.

As shown in FIG. 1C, a surface finishing process is performed on the first metal layer 116a and the second metal layer 116b to form a first finish layer 120a on the first metal layer 116a and to form a second finish layer 120b on the second metal layer 116b, respectively. The first and second finish layers 120a/120b may include at least one of nickel, gold, palladium, tin, and silver, for example. The first and second finish layers 120a/120b may have material compositions that are the same or different, depending on the product requirements. The surface finishing process can include, for example, an electroplating process, an electroless plating process, and/or an immersion process, for example. For instance, the first and/or second finish layers 120a/120b can be a nickel/palladium/gold stacked layer formed by the electroless nickel electroless palladium immersion gold (ENEPIG) technology. Preferably, the first finish layer 120a is not formed on the first central block 118c. As the first central block 118c functions as the die pad, it is preferable not to form the first finish layer thereon, to avoid delamination between the die and the die pad.

In FIG. 1D, the first and second patterned photoresist layers 114a/114b are removed. At this stage, a leadframe structure 100 is obtained. The leadframe structure 100 includes a plurality of inner lead portions 118a/120a, a plurality of outer lead portions 118b/120b, a die pad portion 118c and a heat sink portion 118d/120b. Because the leadframe structure 100 has been formed without the use of etching processes, side surfaces of each of the protruding blocks 118a/118c may be substantially planar and substantially perpendicular to the upper surface 110a of the metal sheet 110. Side surfaces of each protruding block 118a and/or 118e may also be substantially planar and substantially perpendicular to the upper surface of each protruding block 118a and/or 118c, respectively. By “substantially planar,” an applicable surface can exhibit a standard deviation of lateral extent that is less than 30 percent with respect to an average value, such as less than 25 percent or less than 10 percent. The upper surfaces of the protruding blocks 118a/118c, and the lower surfaces of the protruding blocks 118b/118d, may each be substantially coplanar, respectively. FIG. 1D′ is an exemplary top view of the leadframe structure 100 of FIG. 1D. The inner lead portions 118a/120a are disposed surrounding the die pad portion 118c.

As the leadframe structure 100 is formed without the use of etching processes, the finish layers 120a/120b thereon and/or the protruding blocks 118a/118b/118e/118d formed thereon are free from etching damage and provide better product reliability. Furthermore, as the protruding blocks 118a/118b/118c/118c/118d and the finish layers 120a/120b formed thereon protrude from both the upper surface 110a and the lower surface 110b of the metal sheet 110, the protruding blocks 118a/118b/118c/118d have larger contact area and provide better solder joint reliability under board level temperature cycle tests, cyclic bend tests, drop tests, etc.

Referring to FIG. 1E, following FIG. 1D, a chip 130 is attached on the die pad portion 118c and a plurality of wires 140 is provided between the chip 130 and the inner lead portions 118a/120a. Hence, the chip 130 is electrically connected to the inner lead portions 118a/120a through the wires 140.

Next, referring to the FIG. 1F, a molding compound 150 is formed to encapsulate the chip 130, the wires 140, the inner lead portions 118a/120a, and the die pad portion 118c. The molding compound 150 may include, for example, epoxy resins or other applicable polymer material.

Then, referring to FIG. 1G, using the second finish layer 120b as an etching mask, an etching process is performed on the lower surface 110b of the metal sheet 110 to remove portions of the metal sheet 110 that are exposed after removing the second patterned photoresist layer 114b. This etching process exposes the molding compound 150. After the etching process, a plurality of leads (or contact terminals) 125 is formed and each individual lead 125 is physically and electrically isolated from the other leads 125. Each lead 125 includes an inner lead 125a and an outer lead 125b. Also, because the exposed metal sheet 110 is etched off, the etching process further defines the die pad 123. The die pad 123 and the heat sink 127 are separate from the leads 125. Preferably, the etching process can be a wet etching process, for example.

As shown in FIG. 1G, the outer leads 125b protrude downwardly from the molding compound 150, and include portions of the metal sheet 110 that were not removed by the etching process. The outer leads 125b may therefore protrude downwardly from the molding compound 150 by a distance including both the thickness of the metal sheet 110 and the thickness of the protruding metal block 118b. This increases the contact area of the outer leads 125b and provides better solder joint reliability. In addition, a thickness of the heat sink 127 may include the thickness of the metal sheet 110 as well as the thickness of the central protruding block 118d, which increases the exposed surface area of the heat sink 127 and increases the amount of heat that can be dissipated by the heat sink 127.

Finally, referring to FIG. 1H, a singulation process is performed to obtain individual aQFN package structures 10.

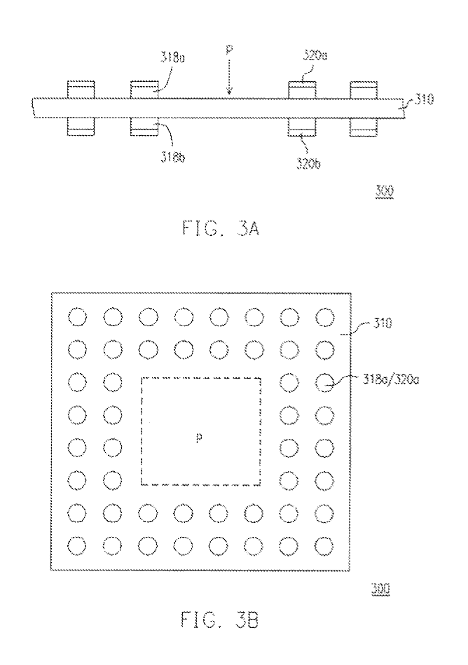

FIG. 2 shows a schematic cross-sectional view of one example of the package structure according to an embodiment of the present invention. Referring to FIG. 2, an aQFN package structure 20 includes a carrier 200, a chip 230, and a plurality of wires 240. The package structure 20 may be formed using the method illustrated in FIGS. 1A-1H.

The carrier 200, for example, a metal leadframe, includes a die pad 223 and a plurality of contact terminals (leads) 225. The leads 225 include a plurality of inner leads 225a and a plurality of outer leads 225b. The inner leads 225a and the outer leads 225b are defined by a molding compound 250; that is, the portions of the leads 225 that are encapsulated by the molding compound 250 are defined as the inner leads 225a, while the outer leads 225b are the exposed portions of the leads 225. The leads 225 are disposed around the die pad 223, and only three columns/rows of the contact terminals 225 are schematically depicted. However, the arrangement of the leads (contact terminals) should not be limited by the exemplary drawings and may be modified according to the product requirements. Specifically, as shown in the partially enlarged view at the right side of FIG. 2, the inner lead 225a includes the finish layer 220a and the first metal block 218a, while the outer leads 225b include the finish layer 220b, the second metal block 218b, and a metal sheet portion (a portion of the metal sheet) 210. Due to the back etching process, the sidewalls of the metal sheet portion 210 and/or the second metal block 218b may be curved. The molding compound 250 encapsulates the chip 230, the wires 240, the die pad 223 and the inner leads 225a, while the outer leads 225b and the heat sink 227 are exposed.

As shown in FIG. 2, the outer leads 225h may therefore protrude downwardly from the molding compound 250 by a distance including both the thickness of the metal sheet 210 and the thickness of the protruding metal block 218b. This increases the contact area of the outer leads 225b and provides better solder joint reliability, which facilitates the electrical connection of this package structure 20 to the next level board to be mounted.

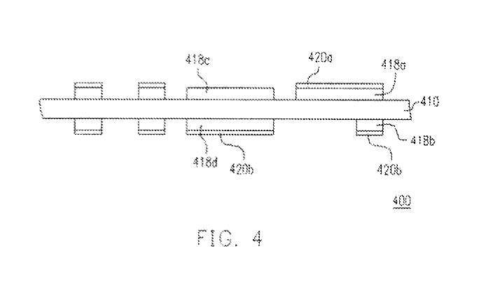

Alternatively, according to another embodiment, the patterns of the first and second patterned photoresist layers are designed to be ball grid array type without the die pad, rather than the land grid array type with the die pad as described above. FIG. 3A shows an exemplary cross-sectional view of the leadframe structure 300, which is obtained following similar process steps to those illustrated by FIGS. 1A-1D. The leadframe structure 300 includes the metal sheet 310, a plurality of inner lead portions 318a/320a, and a plurality of outer lead portions 318b/320b. FIG. 3B is an exemplary top view of the leadframe structure 300 of FIG. 3A. The inner lead portions 118a/120a are disposed surrounding the central space P, which corresponds to the chip placement location (dotted line).

On the other hand, according to another embodiment, the pattern of the first photoresist layer can be designed to be different from that of the second photoresist layer. FIG. 4 shows an exemplary cross-sectional view of the leadframe structure 400, which is obtained following similar process steps to those illustrated by FIGS. 1A-1D. The leadframe structure 400 includes the metal sheet 410, a die pad portion 418c, a plurality of inner lead portions 418a/420a, a heat sink portion 418d/420b, and a plurality of outer lead portions 418b/420b. As the patterns are different, for certain inner lead portions 418a/420a located farther from the die pad portion, the size of the inner lead portions 418a/420a can be designed to be larger than that of the corresponding outer lead portions 418b/420b. The larger inner lead portions 418a/420.a can help shorter the wire-bonding length (e.g., wire-bonded at the position closer to the die pad portion), while the corresponding outer lead portion 418b/420b can be bonded to the board at the position farther from the heat sink portion 418d/420b. In this way, the wire-bonding position of the inner lead portion does not exactly correspond to the bonding position of the corresponding outer lead portion, which may provide better design flexibility.

For the package structures according to the above embodiments, only one back-side etching process is required and the front side is protected by the molding compound during the etching process. Furthermore, the outer leads (terminals) of the package structures are protruded and have stand-off features, which facilitate electrical connectivity and improve product reliability.

It will be apparent to those skilled in the art that various modifications and variations can be made to the structure of embodiments of the present invention without departing from the scope or spirit of the invention. In view of the foregoing, it is intended that the present invention covers modifications and variations of this invention that fall within the scope of the following claims and their equivalents.

What is claimed is:

1. A package structure, comprising:
a chip;
a plurality of leads disposed around the chip and electrically coupled to the chip, wherein at least one of the plurality of leads includes:
a central metal layer having an upper surface and a lower surface;
a first protruding metal block extending upwardly from the upper surface of the central metal layer, and having an upper surface;
a second protruding metal block extending downwardly from the lower surface of the central metal layer, and having a lower surface;
a first finish layer on the upper surface of the first protruding metal block; and
a second finish layer on the lower surface of the second protruding metal block;
a package body formed over the chip and the plurality of leads so that the package body substantially covers the first protruding metal block and the first finish layer of each of the plurality of leads.

2. The package structure of claim 1, wherein:
the first protruding metal block extends upwardly from the upper surface of the central metal layer by between thirty-five percent and one hundred percent of a thickness of the central metal layer; and
the second protruding metal block extends downwardly from the lower surface of the central metal layer by between thirty-five percent and one hundred percent of the thickness of the central metal layer.

3. The package structure of claim 2, wherein the first protruding metal block has a side surface that is substantially perpendicular to the upper surface of the first protruding metal block.

4. The package structure of claim 2, further comprising:
a die pad having an upper surface and a lower surface, the chip being disposed on the upper surface of the die pad;
a first metal layer having an upper surface and a lower surface, the die pad being disposed on the upper surface of the first metal layer, wherein the first metal layer is of substantially the same thickness as the central metal layer;
a second metal layer having an upper surface and a lower surface, the first metal layer being disposed on the upper surface of the second metal layer, wherein the second metal layer is of substantially the same thickness as the second protruding metal block; and
a metal finish layer disposed on the lower surface of the second metal layer.

5. The package structure of claim 4, wherein the upper surface of the die pad is in substantially the same plane as the upper surface of the central metal layer.

6. The package structure of claim 4, wherein the die pad extends upwardly from the upper surface of the first metal layer by between thirty-five percent and one hundred percent of a thickness of the first metal layer.

7. A method of forming a leadframe structure, comprising:
providing a metal sheet, a first patterned photoresist layer formed on an upper surface of the metal sheet, and a second patterned photoresist layer firmed on a lower surface of the metal sheet, wherein a distance between the upper surface and the lower surface corresponds to a thickness of the metal sheet;
forming a first metal layer on areas of the upper surface of the metal sheet not covered by the first patterned photoresist layer and forming a second metal layer on areas of the lower surface of the metal sheet not covered by the second patterned photoresist layer, wherein the first metal layer extends upwardly from the upper surface of the metal sheet by between thirty-five percent and one hundred percent of the thickness of the metal sheet, and wherein the second metal layer extends downwardly from the lower surface of the metal sheet by between thirty-five percent and one hundred percent of the thickness of the metal sheet;
forming a first finish layer on the first metal layer and forming a second finish layer on the second metal layer; and
removing the first and second patterned photoresist layers.

8. The method of claim 7, wherein:
the first metal layer includes a plurality of protruding metal blocks each including an upper surface and a side surface; and
the side surfaces of each of the plurality of protruding metal blocks are substantially perpendicular to the upper surface of the metal sheet.

9. The method of claim 8, wherein the first metal layer and the second metal layer are formed by performing a plating process.

10. The method of claim 8, wherein the first finish layer and the second finish layer are formed by performing a surface finishing process.

11. The method of claim 10, wherein the surface finishing process includes at least one of an electroplating process, an electroless plating process, and an immersion process.

12. A method of making a package structure, comprising:
providing a metal sheet having an upper surface and a lower surface, a plurality of first protruding metal blocks formed on the upper surface, a first finish layer formed on the plurality of first protruding metal blocks, a plurality of second protruding metal blocks formed on the lower surface, and a second finish layer formed on the plurality of second protruding metal blocks;
electrically coupling a chip to at least a first protruding block included in the plurality of first protruding metal blocks;
forming a molding compound over the metal sheet to encapsulate the chip, the plurality of first protruding metal blocks, and the first finish layer formed on the plurality of first protruding metal blocks; and
etching through areas on the lower surface of the metal sheet until the molding compound is exposed, the etching using the second finish layer as an etching mask, so as to define a plurality of leads.

13. The method of claim 12, wherein:
the plurality of first protruding metal blocks extend upwardly from the upper surface of the metal sheet by between thirty-five percent and one hundred percent of a thickness of the metal sheet; and
the plurality of second protruding metal blocks extend downwardly from the lower surface of the metal sheet by between thirty-five percent and one hundred percent of the thickness of the metal sheet.

14. The method of claim 13, wherein the providing comprises:
forming a first patterned photoresist layer on the upper surface of the metal sheet and a second patterned photoresist layer on the lower surface of the metal sheet;
forming the plurality of first protruding metal blocks on areas of the upper surface of the metal sheet that are not covered by the first patterned photoresist layer, and forming the plurality of second protruding metal blocks on areas of the lower surface of the metal sheet that are not covered by the second patterned photoresist layer;
forming the first finish layer on the plurality of first protruding metal blocks and forming the second finish layer on the plurality of second protruding metal blocks; and
removing the first and second patterned photoresist layers.

15. The method of claim 14, wherein the plurality of first protruding metal blocks each include a side surface that is substantially perpendicular to the upper surface of the metal sheet.

16. The method of claim 14, wherein the plurality of first protruding metal blocks and the plurality of second protruding metal blocks are formed by performing a plating process.

17. The method of claim 14, wherein the first finish layer and the second finish layer are formed by performing a surface finishing process.

18. The method of claim 14, wherein the providing further comprises:
forming a first central protruding block on the upper surface of the metal sheet and forming a second central protruding block on the lower surface of the metal sheet, after forming the first and second patterned photoresist layers; and
attaching the chip to an upper surface of the first central protruding block;
wherein the molding compound encapsulates the first central protruding block.

19. The method of claim 18, wherein:
the first central protruding block extends upwardly from the upper surface of the metal sheet by between thirty-five percent and one hundred percent of the thickness of the metal sheet; and
the second central protruding block extends downwardly from the lower surface of the metal sheet by between thirty-five percent and one hundred percent of the thickness of the metal sheet.

20. The method of claim 19, wherein the upper surface of the first central protruding block is substantially in the same plane as an upper surface of the first protruding block included in the plurality of first protruding metal blocks.
